(19) United States
(12) Patent Application Publication
(10) Pub. No.: US 2024/0320400 A1
(43) Pub. Date: Sep. 26, 2024

(54) CROSSOVER SIMULATION AND CAUSATION DETECTION USING SIMULATION ENVIRONMENTS

(71) Applicant: International Business Machines Corporation, Armonk, NY (US)

(72) Inventors: Aaron K. Baughman, Cary, NC (US); Jeremy R. Fox, Georgetown, TX (US); Martin G. Keen, Cary, NC (US); Eduardo Morales, Key Biscayne, FL (US)

(73) Assignee: International Business Machines Corporation, Armonk, NY (US)

(21) Appl. No.: 18/123,710

(22) Filed: Mar. 20, 2023

(51) Int. Cl. G06F 30/27

(52) U.S. Cl. CPC G06F 30/27

(57) ABSTRACT

An embodiment includes identifying a first simulation and a second simulation such that the first simulation is within a threshold similarity of the second simulation. The embodiment generates a set of emergent simulations based at least in part on emergent hyperparameters, where the emergent hyperparameters are generated using the hyperparameters of the first and second simulations. The embodiment selects a subset of the set of emergent simulations according to a diversity metric and detects a causation variable in the selected subset of emergent simulations. The embodiment then generates a predictive simulation using the causation variable.

### BACKGROUND

The present invention relates generally to computer simulations of real-world events. More particularly, the present invention relates to a method, system, and computer program for crossover simulation and causation detection using simulation environments.

A single type of sport, event, game, or situation can occur in many different types of environments. For example, the game of golf can be played as a video game, in the metaverse, or at one of the nearly 40,000 golf courses worldwide. In each of these instances, simulating game play and predicting tournament results involve different techniques.

In some cases, a golf simulator may be made available through a phone or tablet application that includes additional features that enhance the fan experience. For example, an application may allow event attendees to select who to watch, and provide information about what holes to visit, and when to arrive at specific greens, to watch the selected golfer. An application may allow remote audiences to determine which players (or even shots) to watch and when, as well as select their fantasy golf rosters based on scores projected by simulations of game play.

### SUMMARY

The illustrative embodiments provide for crossover simulation and causation detection using simulation environments. An embodiment includes identifying a first simulation and a second simulation such that the first simulation is within a threshold similarity of the second simulation. The embodiment also includes generating a set of emergent simulations based at least in part on emergent hyperparameters, where the emergent hyperparameters are generated using the hyperparameters of the first and second simulations. The embodiment also includes selecting a subset of the set of emergent simulations according to a diversity metric. The embodiment also includes detecting a causation variable in the selected subset of emergent simulations. The embodiment also includes generating a predictive simulation using the causation variable. Other embodiments of this aspect include corresponding computer systems, apparatus, and computer programs recorded on one or more computer storage devices, each configured to perform the actions of the embodiment.

An embodiment includes a computer usable program product. The computer usable program product includes a computer-readable storage medium, and program instructions stored on the storage medium.

An embodiment includes a computer system. The computer system includes a processor, a computer-readable memory, and a computer-readable storage medium, and program instructions stored on the storage medium for execution by the processor via the memory.

### BRIEF DESCRIPTION OF THE DRAWINGS

The novel features believed characteristic of the invention are set forth in the appended claims. The invention itself, however, as well as a preferred mode of use, further objectives, and advantages thereof, will best be understood by reference to the following detailed description of the illustrative embodiments when read in conjunction with the accompanying drawings, wherein:

FIG. 1 depicts a block diagram of a computing environment in accordance with an illustrative embodiment;

FIG. 2 depicts a block diagram of an example service infrastructure in accordance with an illustrative embodiment;

FIG. 3 depicts a block diagram of an exemplary simulation generation module in accordance with an illustrative embodiment;

FIG. 4 depicts a block diagram of an exemplary simulation similarity module in accordance with an illustrative embodiment;

FIG. 5 depicts a block diagram of an exemplary emergent simulation module in accordance with an illustrative embodiment;

FIG. 6 depicts a block diagram of an exemplary diversity optimization module in accordance with an illustrative embodiment;

FIG. 7 depicts a flowchart of an example process for crossover simulation and causation detection using simulation environments in accordance with an illustrative embodiment;

FIG. 8 depicts a flowchart of an example process for identifying similar simulation environments in accordance with an illustrative embodiment;

FIG. 9 depicts a flowchart of an example process for generating emergent simulations in accordance with an illustrative embodiment; and

FIG. 10 depicts a flowchart of an example process for diversity optimization in accordance with an illustrative embodiment; and

FIG. 11 depicts a block diagram of exemplary chromosomal representations and operations in accordance with an illustrative embodiment.

### DETAILED DESCRIPTION

Simulations of events, environments, attractions, and courses have quickly grown in popularity. As a result, there has been a growing interest in expanding the selection of currently available simulation environments. The accuracy of existing simulations demonstrates the capability of building more simulation environments.

However, just within the domain of sports, and further narrowed to golf alone, there are almost 40,000 courses worldwide that could be simulated. If the possibilities are expanded to other sports, and then to other domains, the list of potential environments quickly grows unwieldy and not impractical using prior techniques.

While it is demonstrably possible to build such simulations, the process using previous techniques is very time consuming and tedious. One reason for this is because simulators, such as a Monte Carlo algorithm, are fine tuned to a specific environment. Usually, simulators have dozens of predictive models that are optimized using numerous optimization techniques.

The present disclosure addresses these and other challenges. According to some embodiments, many point cross over of simulator hyper parameters using optimization techniques (e.g., quadratic unconstrained binary optimization) allows for the generation of many emergent environments. These many environments provide diversity of the environments, which allows for the detection of causation variable through invariant measurements of models. This knowledge of causation variables allows for accurate simulations to be more quickly realized. The causation variables allow for understanding which patterns are useful and solves the correlation-versus-causation dilemma, since spurious correlations stemming from data biases are unrelated to the causal explanation of interest.

In exemplary embodiments, a bank of simulation environments is available within a simulation environment repository. The simulation environment repository comprises repository management software running on a computer readable storage medium and provides persistent data storage for simulation environments. Various embodiments can include other types of software, such as database or document management software.

In exemplary embodiments, a process extracts simulation environment data for pairs of simulation environments. The process performs similarity processing on each of the extracted pairs of simulation environments. In various embodiments, the similarity processing includes various types of comparisons, such as comparison of the source code, code comments, hyperparameters, simulated characteristics, etc. In some embodiments, the process quantifies the similarity by applying a score indicative of a degree of similarity of the two simulation environments being evaluated. In some such embodiments, the score may be indicative of a percentage of identical aspects of the two simulation environments. In some embodiments, the process compares the similarity score to a threshold value that is determinative of whether the two simulation environments are considered to be sufficiently similar to proceed.

In exemplary embodiments, the process receives the similar environments from the simulation similarity module. The process uses the hyperparameters of the similar environments to generate sets of emergent hyperparameters that are used to generate emergent simulation environments.

In exemplary embodiments, the process receives the emergent simulation environments generated by the emergent simulations module. The process analyzes the emergent simulation environments to identify those that provide for maximum diversity amongst a set of simulation environments.

In exemplary embodiments, a simulation environment repository receives the emergent simulations from the process that have been identified as providing optimal diversity. The simulation environment repository analyzes the emergent simulations to detect causation variables. For example, depending on the type of simulation, a causation variable may relate to causation of a player performing well or winning.

Detecting such a causation within a single environment is difficult. Many times, explanations generated from a simulation are related to correlation rather than causation. However, embodiments disclosed herein are able to detect invariant conditional distributions for causation recording invariant conditional using several simulator environments. In exemplary embodiments, the process uses the causation variables to generate a new simulation environment.

For the sake of clarity of the description, and without implying any limitation thereto, the illustrative embodiments are described using some example configurations. From this disclosure, those of ordinary skill in the art will be able to conceive many alterations, adaptations, and modifications of a described configuration for achieving a described purpose, and the same are contemplated within the scope of the illustrative embodiments.

Furthermore, simplified diagrams of the data processing environments are used in the figures and the illustrative embodiments. In an actual computing environment, additional structures or components that are not shown or described herein, or structures or components different from those shown but for a similar function as described herein may be present without departing the scope of the illustrative embodiments.

Furthermore, the illustrative embodiments are described with respect to specific actual or hypothetical components only as examples. Any specific manifestations of these and other similar artifacts are not intended to be limiting to the invention. Any suitable manifestation of these and other similar artifacts can be selected within the scope of the illustrative embodiments.

The examples in this disclosure are used only for the clarity of the description and are not limiting to the illustrative embodiments. Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

Furthermore, the illustrative embodiments may be implemented with respect to any type of data, data source, or access to a data source over a data network. Any type of data storage device may provide the data to an embodiment of the invention, either locally at a data processing system or over a data network, within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, computer readable storage media, high-level features, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and are not limiting to the illustrative embodiments. Additional data, operations, actions, tasks, activities, and manipulations will be conceivable from this disclosure and the same are contemplated within the scope of the illustrative embodiments.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation, or garbage collection, but this does not render the storage device as transitory because the data is not transitory while it is stored.

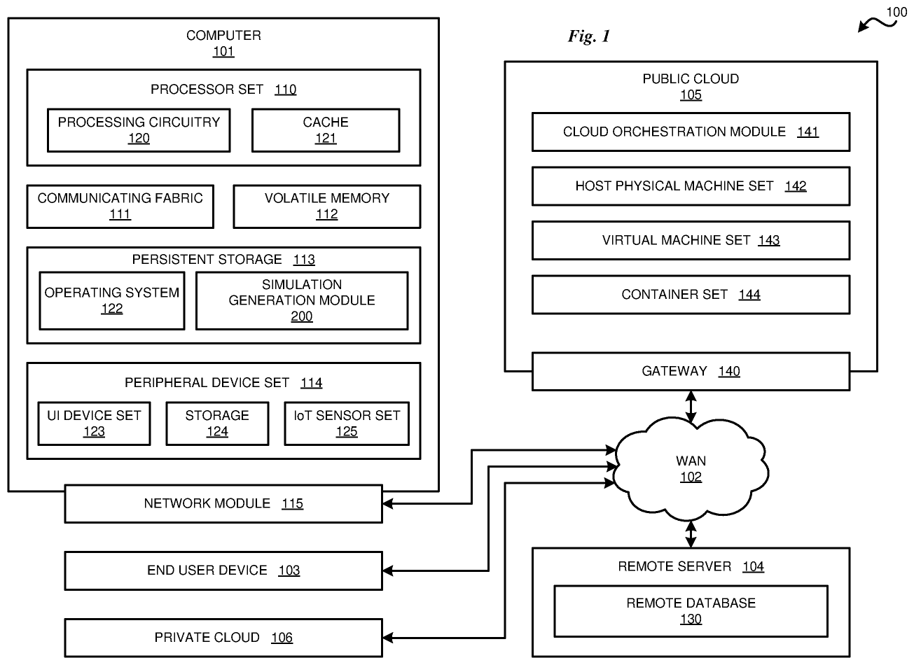

With reference to FIG. 1, this figure depicts a block diagram of a computing environment 100. Computing environment 100 contains an example of an environment for the execution of at least some of the computer code involved in performing the inventive methods, such as an improved simulation generation module 200 that provides crossover simulation and causation detection using simulation environments. In addition to simulation generation module 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and simulation generation module 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network, or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in simulation generation module 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in simulation generation module 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Measured service: cloud systems automatically control and optimize resource use by leveraging a metering capability at some level of abstraction appropriate to the type of service (e.g., storage, processing, bandwidth, and active user accounts). Resource usage can be monitored, controlled, reported, and invoiced, providing transparency for both the provider and consumer of the utilized service.

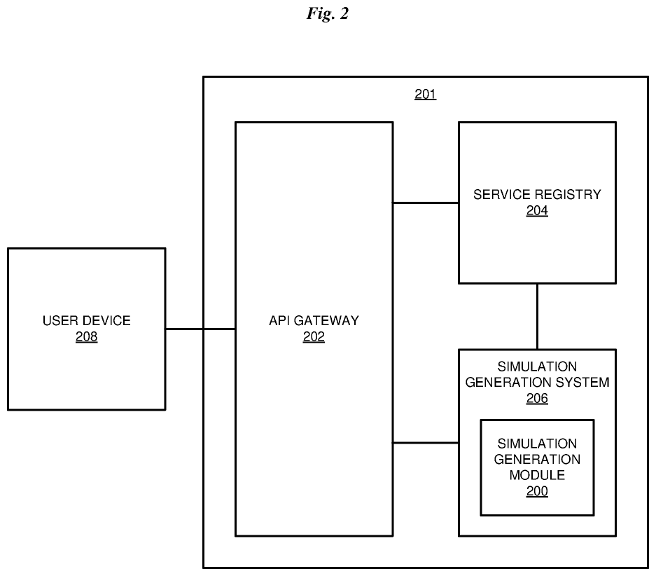

With reference to FIG. 2, this figure depicts a block diagram of an example service infrastructure 201 in accordance with an illustrative embodiment. In the illustrated embodiment, the service infrastructure 201 includes a simulation generation system 206. In an embodiment, the simulation generation system 206 is an example of the computer 101 of FIG. 1 and includes the simulation generation module 200 of FIG. 1.

In the illustrated embodiment, the service infrastructure 201 provides services and service instances to a user device 208. User device 208 communicates with service infrastructure 201 via an API gateway 202. API gateway 202 provides access to client applications like the simulation generation module 200. API gateway 202 receives service requests issued by client applications and creates service lookup requests based on service requests. As a non-limiting example, in an embodiment, the user device 208 executes a routine to initiate interaction with the simulation generation module 200. For instance, in some embodiments, the user device 208 executes a routine to initiate simulation generation processes of the simulation generation module 200 such as described in connection with the embodiments disclosed herein.

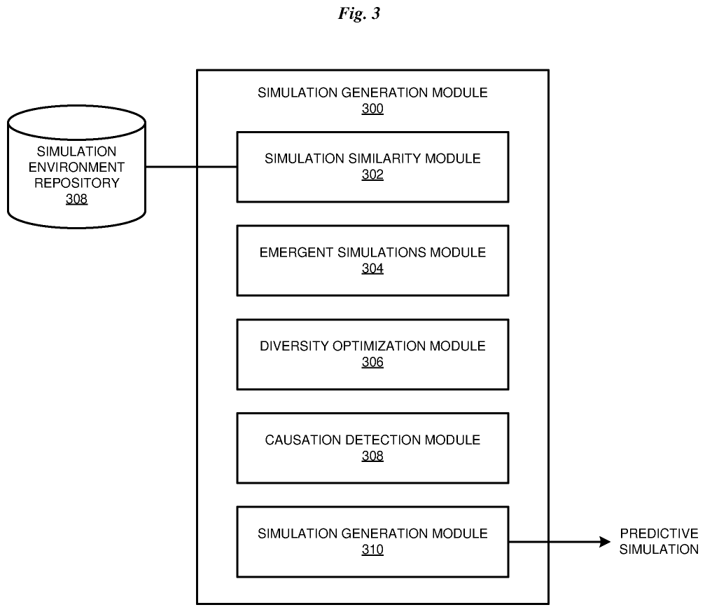

With reference to FIG. 3, this figure depicts a block diagram of an exemplary simulation generation module 300 in accordance with an illustrative embodiment. In the illustrated embodiment, the simulation generation module 300 is an example of the simulation generation module 200 of FIGS. 1 and 2.

In the illustrated embodiment, the simulation generation module 300 includes a simulation similarity module 302, an emergent simulations module 304, a diversity optimization module 306, a simulation environment repository 308, and a simulation generation module 310. In alternative embodiments, the simulation generation module 300 can include some or all of the functionality described herein but grouped differently into one or more modules. In some embodiments, the functionality described herein is distributed among a plurality of systems, which can include combinations of software and/or hardware based systems, for example Application-Specific Integrated Circuits (ASICs), computer programs, or smart phone applications.

In the illustrated embodiment, a bank of simulation environments is available within a simulation environment repository 308. The simulation environment repository 308 comprises repository management software running on a computer readable storage medium and provides persistent data storage for simulation environments. While only one simulation environment repository 308 is shown as a database, alternative embodiments include other types of software, such as database or document management software.

The simulation similarity module 302 extracts simulation environment data for pairs of simulation environments. The simulation similarity module 302 performs similarity processing on each of the extracted pairs of simulation environments. In various embodiments, the similarity processing includes various types of comparisons, such as comparison of the source code, code comments, hyperparameters, simulated characteristics, etc. In some embodiments, the simulation similarity module 302 quantifies the similarity by applying a score indicative of a degree of similarity of the two simulation environments being evaluated. In some such embodiments, the score may be indicative of a percentage of identical aspects of the two simulation environments. In some embodiments, the simulation similarity module 302 compares the similarity score to a threshold value that is determinative of whether the two simulation environments are considered to be sufficiently similar to proceed.

In the illustrated embodiment, the emergent simulations module 304 receives the similar environments from the simulation similarity module 302. The emergent simulations module 304 uses the hyperparameters of the similar environments to generate sets of emergent hyperparameters that are used to generate emergent simulation environments.

In the illustrated embodiment, the diversity optimization module 306 receives the emergent simulation environments generated by the emergent simulations module 304. The diversity optimization module 306 analyzes the emergent simulation environments to identify those that provide for maximum diversity amongst a set of simulation environments.

In the illustrated embodiment, the simulation environment repository 308 receives the emergent simulations from the diversity optimization module 306 that have been identified as providing optimal diversity. The simulation environment repository 308 analyzes the emergent simulations to detect causation variables. For example, depending on the type of simulation, a causation variable may relate to causation of a player performing well or winning. Detecting such a causation within a single environment is difficult. Many times, explanations generated from a simulation are related to correlation rather than causation. However, embodiments disclosed herein are able to detect invariant conditional distributions for causation recording invariant conditional using several simulator environments. In the illustrated embodiment, the simulation generation module 310 uses the causation variables to generate a new simulation environment.

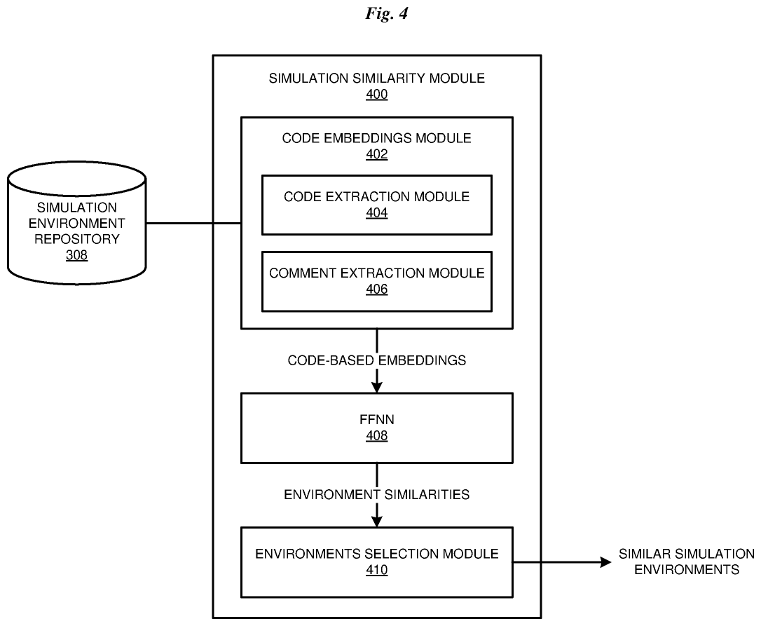

With reference to FIG. 4, this figure depicts a block diagram of an exemplary simulation similarity module 400 in accordance with an illustrative embodiment. In the illustrated embodiment, the simulation similarity module 400 is an example of the simulation similarity module 302 of FIG. 3.

In the illustrated embodiment, the simulation similarity module 400 includes a code embeddings module 402, a Feed Forward Neural Network (FFNN) 408, and an environments selection module 410. The code embeddings module 402 includes a code extraction module 404 and a comment extraction module 406. In alternative embodiments, the simulation similarity module 400 can include some or all of the functionality described herein but grouped differently into one or more modules. In some embodiments, the functionality described herein is distributed among a plurality of systems, which can include combinations of software and/or hardware based systems, for example Application-Specific Integrated Circuits (ASICs), computer programs, or smart phone applications.

In the illustrated embodiment, the simulation similarity module 400 generates code embeddings for a plurality of predictive simulations, and determines similarities of pairs of the plurality of predictive simulations. The FFNN 408 determines the similarity of each input pair of simulation environments. In order to do so, the code embeddings module 402 uses a code extraction module 404 that encodes source code and a comment extraction module 406 that encodes comments in the source code. The code embeddings module 402 thus generates embeddings from pairs of simulation models by converting source code or comments to high-dimensional vectors (e.g., feature vectors) in a semantic space using any suitable word embedding model, non-limiting examples of which can include, but are not limited to, Word2vec model, GloVe, Long short-term memory (LSTM) learning, convolutional neural network (CNN, or ConvNet) learning, Gated Recurrent Unit (GRU) learning, Deep Learning, Attention Mechanism Deep Learning, Recurrent Neural Network (RNN), neural networks, Principal Component Analysis (PCA), T-Distributed Stochastic Neighbour Embedding (t-SNE) or any other suitable word embedding model.

The embeddings are input into the FFNN 408 to determine the similarity of each simulation environment with others. The environments selection module 410 then selects the two most similar simulation environments to serve as parents for generating several emergent simulations.

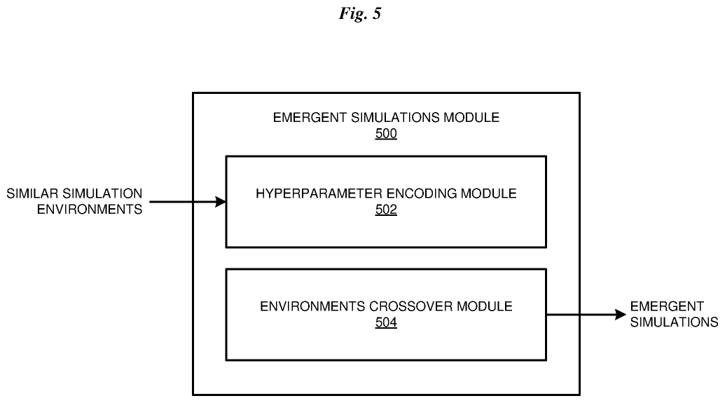

With reference to FIG. 5, this figure depicts a block diagram of an exemplary emergent simulation module 500 in accordance with an illustrative embodiment. In the illustrated embodiment, the emergent simulations module 500 is an example of the emergent simulations module 304 of FIG. 3.

In the illustrated embodiment, the emergent simulations module 500 includes a hyperparameter encoding module 502 and an environments crossover module 504. In alternative embodiments, the emergent simulations module 500 can include some or all of the functionality described herein but grouped differently into one or more modules. In some embodiments, the functionality described herein is distributed among a plurality of systems, which can include combinations of software and/or hardware based systems, for example Application-Specific Integrated Circuits (ASICs), computer programs, or smart phone applications.

In the illustrated embodiment, the hyperparameter encoding module 502 encodes each of the hyper parameters that describe the associated simulation environment, such as a Monte Carlo simulation, into a chromosomal representation. The binary bits encode sampling rates, jitter, post processor inclusion and etc. Each environment has a binary or chromosomal representation that crossed over several times to produce many offspring that are called emergent simulations.

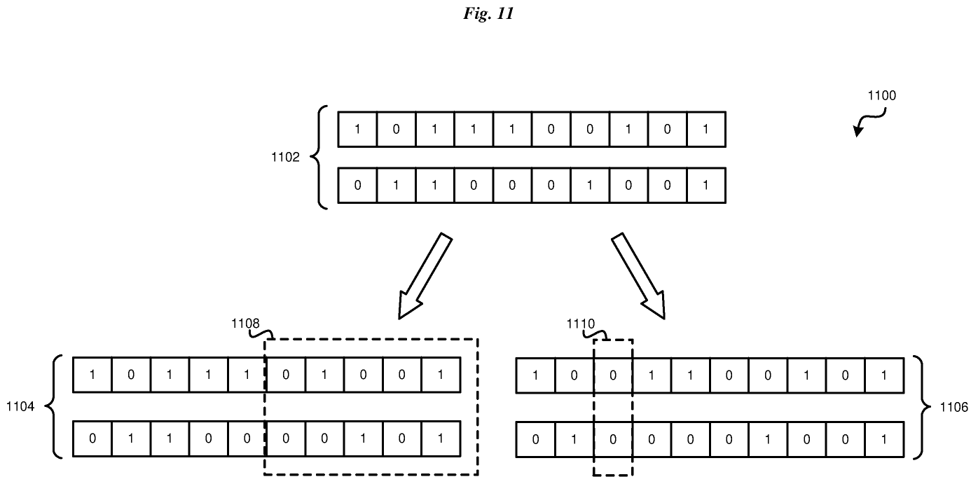

Referring now also to FIG. 11, this figure depicts a block diagram 1100 of exemplary chromosomal representations and operation in accordance with an illustrative embodiment. In the illustrated embodiment, hyper parameters from parent simulation environments are represented as chromosome pair 1102 in which various hyper parameters from one parent are encoded into a top row of bit strings, and the same hyper parameters from the other parent are encoded into a bottom row of bit strings. Thus, the bit strings vary according to the values of the hyper parameters. Emergent simulations are then created by performing operations on the bit strings of the parent chromosome pair 1102. For example, a crossover swaps portions of the parent bit strings enclosed in broken line 1108 resulting in emergent chromosome pair 1104. As another example, individual bits are mutated to different values from the parents as indicated in broken line access control system interface 1110, resulting in emergent chromosome pair 1106.

Referring again to FIG. 5, in an exemplary embodiment, the hyperparameter encoding module 502 encodes the hyper parameters into binary bits for sampling rates, jitter, post processor inclusion, and any other desired hyper parameters. The environments crossover module 504 performs multiple crossover operations on the received similar simulation environments, result in several emergent simulations.

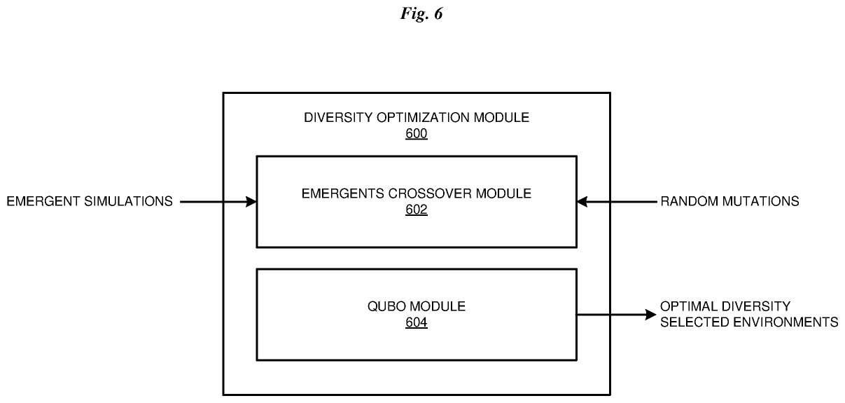

With reference to FIG. 6, this figure depicts a block diagram of an exemplary diversity optimization module 600 in accordance with an illustrative embodiment. In the illustrated embodiment, the diversity optimization module 600 is an example of the diversity optimization module 306 of FIG. 3.

In the illustrated embodiment, the diversity optimization module 600 includes a emergents crossover module 602 and a QUBO module 604. In alternative embodiments, the simulation similarity module 400 can include some or all of the functionality described herein but grouped differently into one or more modules. In some embodiments, the functionality described herein is distributed among a plurality of systems, which can include combinations of software and/or hardware based systems, for example Application-Specific Integrated Circuits (ASICs), computer programs, or smart phone applications.

In the illustrated embodiment, the emergents crossover module 602 encodes each of the hyper parameters of the emergent simulations generated by the environments crossover module 504 of FIG. 5 into a chromosomal representations. The emergents crossover module 602 then performs multiple crossover operations on these to generate second generation offspring from the similar simulation environments identified by the simulation similarity module 400. In some embodiments, the emergents crossover module 602 also randomly introduces a random mutation into one of the chromosomal representations.

Once a large number of second generation emergents have been generated, the QUBO module 604 uses a quadratic unconstrained binary optimization (QUBO) algorithm that identifies a subset of the second generation emergents as the combination of emergent simulation environments that provide the most (optimal) diversity.

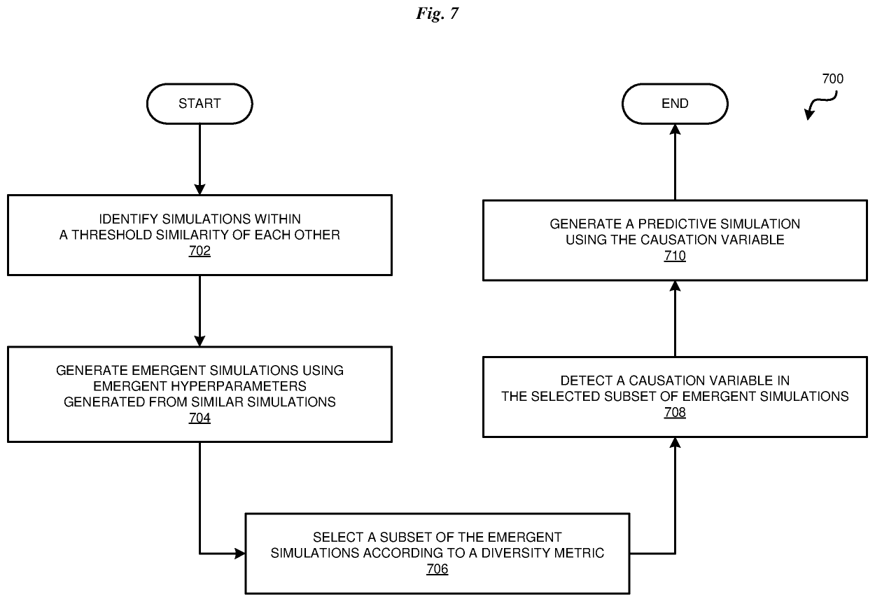

With reference to FIG. 7, this figure depicts a flowchart of an example process 700 for crossover simulation and causation detection using simulation environments in accordance with an illustrative embodiment. In a particular embodiment, the simulation generation module 200 of FIGS. 1 and 2 carries out the process 700.

In the illustrated embodiment, at block 702, the process identifies simulations within a threshold similarity of each other. Next, at block 704, the process generates emergent simulations using emergent hyperparameters generated from similar simulations. Next, at block 706, the process selects a subset of the emergent simulations according to a diversity metric. Next, at block 708, the process detects a causation variable in the selected subset of emergent simulations. Next, at block 710, the process generates a predictive simulation using the causation variable.

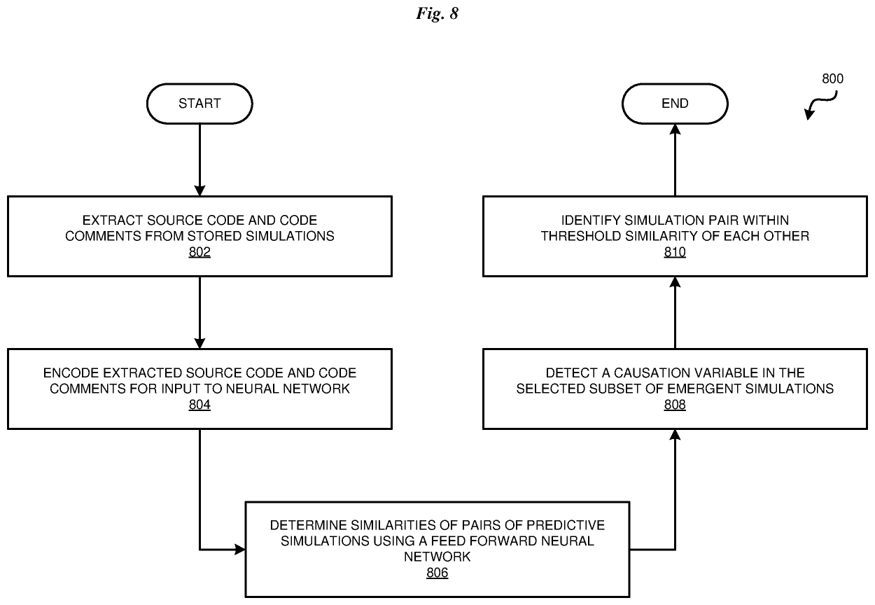

With reference to FIG. 8, this figure depicts a flowchart of an example process 800 for identifying similar simulation environments in accordance with an illustrative embodiment. In a particular embodiment, the simulation similarity module 400 of FIG. 4 carries out the process 800.

In the illustrated embodiment, at block 802, the process extracts source code and code comments from stored simulations. Next, at block 804, the process encodes extracted source code and code comments for input to neural network. Next, at block 806, the process determines similarities of pairs of predictive simulations using a feed forward neural network. Next, at block 808, the process detects a causation variable in the selected subset of emergent simulations. Next, at block 810, the process identifies a simulation pair within a threshold similarity of each other.

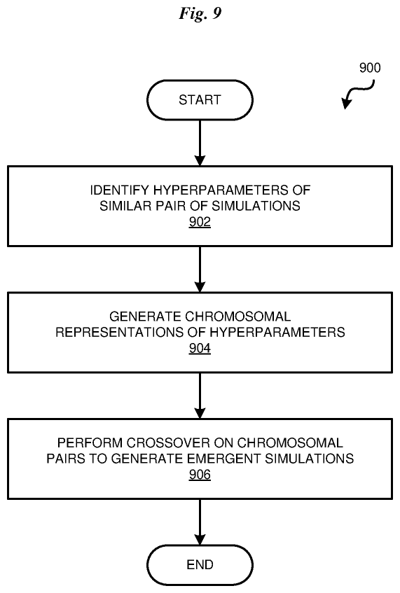

With reference to FIG. 9, this figure depicts a flowchart of an example process 900 for generating emergent simulations in accordance with an illustrative embodiment. In a particular embodiment, the emergent simulations module 500 of FIG. 5 carries out the process 900.

In the illustrated embodiment, at block 902, the process identifies hyperparameters of the similar pair of simulations. Next, at block 904, the process generates chromosomal representations of hyperparameters. Next, at block 906, the process performs crossover operations on chromosomal pairs to generate emergent simulations.

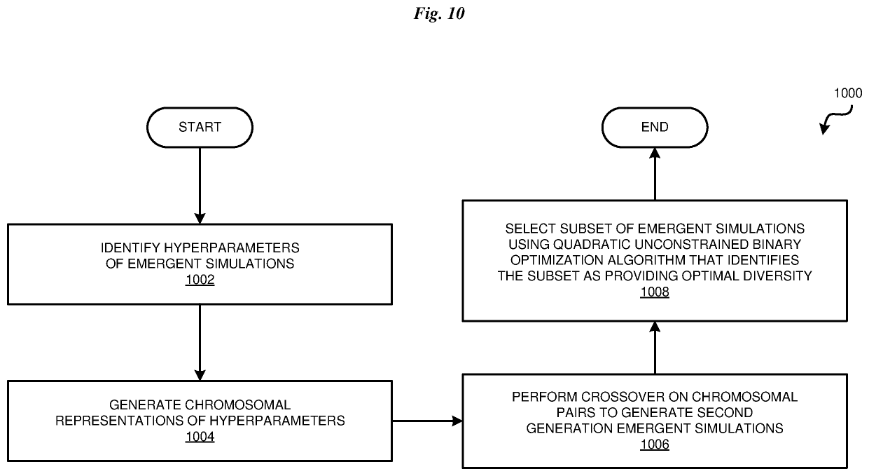

With reference to FIG. 10, this figure depicts a flowchart of an example process 1000 for diversity optimization in accordance with an illustrative embodiment. In a particular embodiment, the diversity optimization module 600 of FIG. 6 carries out the process 1000.

In the illustrated embodiment, at block 1002, the process identifies hyperparameters of emergent simulations. Next, at block 1004, the process generates chromosomal representations of hyper parameters. Next, at block 1006, the process performs crossover operations on chromosomal pairs to generate second generation emergent simulations. Next, at block 1008, the process selects a subset of emergent simulations using quadratic unconstrained binary optimization algorithm that identifies the subset as providing optimal diversity.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “illustrative” is used herein to mean “serving as an example, instance or illustration.” Any embodiment or design described herein as “illustrative” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

Thus, a computer implemented method, system or apparatus, and computer program product are provided in the illustrative embodiments for managing participation in online communities and other related features, functions, or operations. Where an embodiment or a portion thereof is described with respect to a type of device, the computer implemented method, system or apparatus, the computer program product, or a portion thereof, are adapted or configured for use with a suitable and comparable manifestation of that type of device.

Where an embodiment is described as implemented in an application, the delivery of the application in a Software as a Service (SaaS) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

The present invention may be a system, a method, and/or a computer program product at any possible technical detail level of integration. The computer program product may include a computer readable storage medium (or media) having computer readable program instructions thereon for causing a processor to carry out aspects of the present invention.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Embodiments of the present invention may also be delivered as part of a service engagement with a client corporation, nonprofit organization, government entity, internal organizational structure, or the like. Aspects of these embodiments may include configuring a computer system to perform, and deploying software, hardware, and web services that implement, some or all of the methods described herein. Aspects of these embodiments may also include analyzing the client's operations, creating recommendations responsive to the analysis, building systems that implement portions of the recommendations, integrating the systems into existing processes and infrastructure, metering use of the systems, allocating expenses to users of the systems, and billing for use of the systems. Although the above embodiments of present invention each have been described by stating their individual advantages, respectively, present invention is not limited to a particular combination thereof. To the contrary, such embodiments may also be combined in any way and number according to the intended deployment of present invention without losing their beneficial effects.

What is claimed is:

1. A computer-implemented method comprising:
identifying a first simulation and a second simulation such that the first simulation is within a threshold similarity of the second simulation;
generating a set of emergent simulations based at least in part on emergent hyperparameters, wherein the emergent hyperparameters are generated using hyperparameters of the first and second simulations;
selecting a subset of the set of emergent simulations according to a diversity metric;
detecting a causation variable in the selected subset of emergent simulations; and
generating a predictive simulation using the causation variable.

2. The method of claim 1, wherein the identifying of the first simulation and the second simulation further comprises:
generating code embeddings for a plurality of predictive simulations; and
determining similarities of pairs of the plurality of predictive simulations.

3. The method of claim 2, wherein the generating of the code embeddings comprises encoding source code and code comments for the plurality of predictive simulations.

4. The method of claim 2, wherein the determining of the similarities of pairs of the plurality of predictive simulations comprises using a feed forward neural network to determine the similarities based at least in part on the code embeddings.

5. The method of claim 1, wherein the generating of the set of emergent simulations comprises:
generating first generation offspring from the first and second simulations; and
generating second generation offspring from the first generation offspring.

6. The method of claim 5, further comprising generating the emergent hyperparameters by performing a crossover operation on chromosomal representations of the hyperparameters of the first and second simulations.

7. The method of claim 5, further comprising generating the second generation offspring by performing a crossover operation on chromosomal representations of hyperparameters of pairs of first generation offspring.

8. The method of claim 7, wherein the generating of the second generation offspring further comprises introducing a random mutation into one of the chromosomal representations.

9. The method of claim 1, wherein the selecting of the subset of the set of emergent simulations comprises using a quadratic unconstrained binary optimization algorithm that identifies the subset as providing optimal diversity.

10. The method of claim 1, wherein the detecting of the causation variable comprises detecting a variable having invariance across the subset of emergent simulations.

11. The method of claim 1, wherein the first simulation and the second simulation are selected from among a plurality of predictive simulations stored in a repository.

12. A computer program product comprising one or more computer readable storage media, and program instructions collectively stored on the one or more computer readable storage media, the program instructions executable by a processor to cause the processor to perform operations comprising:
identifying a first simulation and a second simulation such that the first simulation is within a threshold similarity of the second simulation;
generating a set of emergent simulations based at least in part on emergent hyperparameters, wherein the emergent hyperparameters are generated using hyperparameters of the first and second simulations;
selecting a subset of the set of emergent simulations according to a diversity metric;
detecting a causation variable in the selected subset of emergent simulations; and
generating a predictive simulation using the causation variable.

13. The computer program product of claim 12, wherein the stored program instructions are stored in a computer readable storage device in a data processing system, and wherein the stored program instructions are transferred over a network from a remote data processing system.

14. The computer program product of claim 12, wherein the stored program instructions are stored in a computer readable storage device in a server data processing system, and wherein the stored program instructions are downloaded in response to a request over a network to a remote data processing system for use in a computer readable storage device associated with the remote data processing system, further comprising:
program instructions to meter use of the program instructions associated with the request; and
program instructions to generate an invoice based on the metered use.

15. The computer program product of claim 12, wherein the generating of the set of emergent simulations comprises:
generating first generation offspring from the first and second simulations; and
generating second generation offspring from the first generation offspring.

16. The computer program product of claim 15, further comprising generating the emergent hyperparameters by performing a crossover operation on chromosomal representations of the hyperparameters of the first and second simulations.

17. The computer program product of claim 15, further comprising generating the second generation offspring by performing a crossover operation on chromosomal representations of hyperparameters of pairs of first generation offspring.

18. A computer system comprising a processor and one or more computer readable storage media, and program instructions collectively stored on the one or more computer readable storage media, the program instructions executable by the processor to cause the processor to perform operations comprising:
identifying a first simulation and a second simulation such that the first simulation is within a threshold similarity of the second simulation;
generating a set of emergent simulations based at least in part on emergent hyperparameters, wherein the emergent hyperparameters are generated using hyperparameters of the first and second simulations;
selecting a subset of the set of emergent simulations according to a diversity metric;
detecting a causation variable in the selected subset of emergent simulations; and
generating a predictive simulation using the causation variable.

19. The computer system of claim 18, wherein the generating of the set of emergent simulations comprises:
generating first generation offspring from the first and second simulations; and
generating second generation offspring from the first generation offspring.

20. The computer system of claim 19, further comprising generating the emergent hyperparameters by performing a crossover operation on chromosomal representations of the hyperparameters of the first and second simulations.
